(19) United States
(12) Patent Application Publication
(10) Pub. No.: US 2025/0309868 A1
(43) Pub. Date: Oct. 2, 2025

(54) SWITCH DEVICE AND LOAD DRIVING SYSTEM

(71) Applicant: ROHM CO., LTD., Kyoto-shi (JP)

(72) Inventor: Tetsuo YAMATO, Kyoto-shi (JP)

(21) Appl. No.: 19/089,579

(22) Filed: Mar. 25, 2025

(30) Foreign Application Priority Data
Mar. 27, 2024 (JP) 2024-050692

(51) Int. Cl. H03K 3/011

(52) U.S. Cl. CPC H03K 3/011

(57) ABSTRACT

The switch device includes an input terminal, an output terminal, an output transistor provided between the input terminal and the output terminal, and a control circuit configured to, under its control, turn on or off the output transistor in response to a control signal. The control circuit is enabled to execute a protective operation by which the output transistor is switched over from on to off independent of the control signal on a basis of an outside temperature of the switch device and an output current flowing through the output transistor.

### CROSS-REFERENCE TO RELATED APPLICATIONS

The present invention claims priority under 35 U.S.C. § 119 to Japanese Application No. 2024-050692 filed in Japan on Mar. 27, 2024, the entire contents of which are hereby incorporated by reference.

### TECHNICAL FIELD

The present disclosure relates to a switch device and a load driving system.

### RELATED ART

There has been provided heretofore a switch device that operates to make electrical continuity or shutdown between two terminals by turning on or off an output transistor, which is provided between the two terminals, in response to an inputted control signal.

### CITATION LIST

### Patent Literature

Patent Document 1: WO 2019/065395

### DESCRIPTION OF THE DRAWINGS

FIG. 1 is an overall configuration diagram of a load driving system according to an embodiment of the present disclosure.

FIG. 2 is an appearance perspective view of a switch device according to the embodiment of the disclosure.

FIG. 3 is an outlined configuration diagram of a vehicle according to the embodiment of the disclosure.

FIG. 4 is an explanatory chart of three regions according to the embodiment of the disclosure and concerning safety of interconnections.

FIG. 5 is an operation flowchart of the switch device according to the embodiment of the disclosure.

FIG. 6 is an explanatory chart according to the embodiment of the disclosure and concerning a relationship of protective current value versus protection activating time.

FIG. 7 is an explanatory chart according to the embodiment of the disclosure and concerning a relationship of protective current value versus protection activating time.

FIG. 8 is a chart according to the embodiment of the disclosure and showing an aspect in which a relationship of protective current value versus protection activating time varies in response to outside temperature.

FIG. 9 is a chart according to a first practical example belonging to the embodiment of the disclosure and showing a relationship of protective current value versus protection activating time versus outside temperature.

FIG. 10 is a chart according to the first practical example belonging to the embodiment of the disclosure and showing an aspect in which an output current varies.

FIG. 11 is a chart according to a second practical example belonging to the embodiment of the disclosure, and showing a relationship of protective current value versus protection activating time versus outside temperature.

FIG. 12 is a chart according to the second practical example belonging to the embodiment of the disclosure and showing an aspect in which the output current varies.

FIG. 13 is a chart according to a third practical example belonging to the embodiment of the disclosure and showing six candidates for overcurrent protection characteristics.

FIG. 14 is an overall configuration diagram of a modified load driving system according to a fourth practical example belonging to the embodiment of the disclosure.

FIG. 15 is an explanatory diagram of a configuration for output current detection according to a fifth practical example belonging to the embodiment of the disclosure.

FIG. 16 is an explanatory diagram of a configuration for output current detection according to a sixth practical example belonging to the embodiment of the disclosure.

### DETAILED DESCRIPTION OF PREFERRED EMBODIMENTS

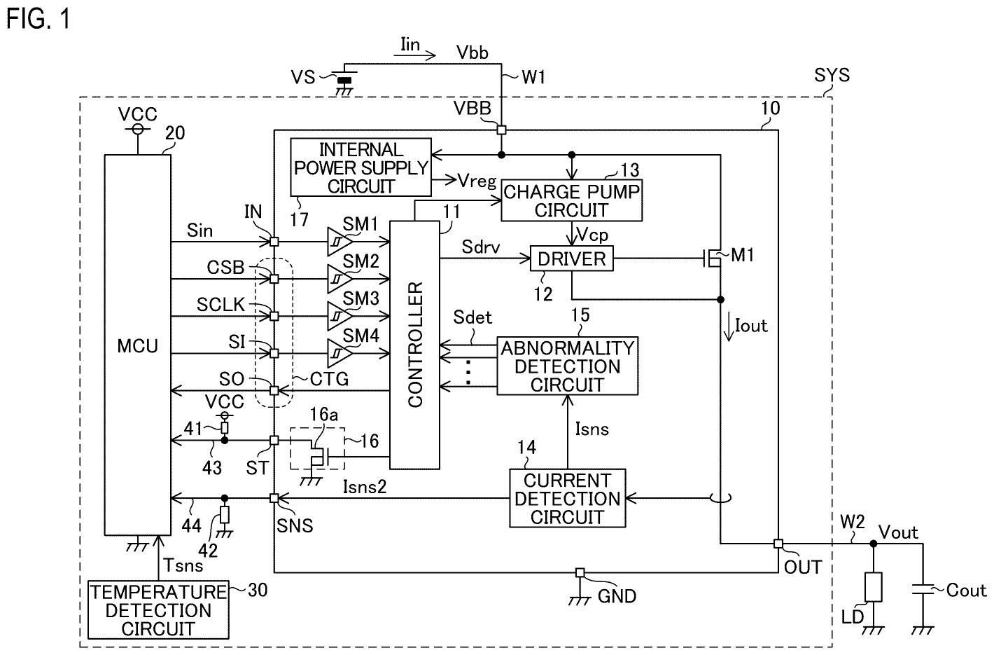

Hereinafter, an example of an embodiment of the present disclosure will be described concretely with reference to the accompanying drawings. Throughout the individual figures for reference, like members are designated by like reference signs, with overlapping descriptions of like members omitted in principle. In addition, herein, for the sake of simplified description, designations of information, signals, physical quantities, functional units, circuits, devices or components, and the like may be omitted or abbreviated, from time to time, while symbols or signs referring to those information, signals, physical quantities, functional units, circuits, devices or components, and the like are expressed instead. For example, a later-described output wiring (see FIG. 1) to be referred to by “W2” may be expressed as output wiring W2 or abbreviated as wiring W2, where both means the same.

First provided is an explanation of several terms that are used in description of the embodiment of the disclosure. “Ground” refers to a reference conductor having a potential of 0V (zero volts) serving as a reference or refers to the 0V potential itself. The reference conductor may be formed by using a metal or other conductor. The 0V potential may otherwise be referred to as ground potential. Ground potential and ground voltage are synonymous with each other. In the embodiment of the disclosure, voltages provided without any particular reference represent potentials as viewed from the ground.

The term, level, refers to a level of electric potential. As for any focused signal or voltage, the term, high level, refers to a potential higher than low level. As for any focused signal or voltage, that a signal or voltage is at high level means, strictly, that a level of the signal or voltage is at high level. Similarly, that a signal or voltage is at low level means, strictly, that a level of the signal or voltage is at low level. A level relating to signals may be expressed as signal level, and a level relating to voltages may be expressed as voltage level.

As to an arbitrary signal having a signal level, either high level or low level, a period during which the signal level is held at high level is referred to as high-level period, and a period during which the signal level is held at low level is referred to as low-level period. This is also applicable to an arbitrary voltage having a voltage level, either high level or low level.

In connection with an arbitrary transistor consisting of a FET (Field Effect Transistor) exemplified by MOSFETs, an on state refers to a state in which there is electrical continuity between drain and source of the transistor, while an off state refers to a state in which there is no electrical continuity between drain and source of the transistor (a shutdown state). This is applicable also to transistors not categorized into FETs. MOSFETs can be regarded as enhancement mode MOSFETs unless otherwise specified. The term “MOSFET” is an abbreviation of “Metal-Oxide-Semiconductor Field-Effect Transistor”. Also, in an arbitrary MOSFET, unless otherwise specified, it may appropriately be considered that the back gate is short-circuited to the source.

Connections or interconnections between or among a plurality of circuit-forming component sites such as arbitrary circuit elements, wirings and nodes may be construed as electrical connections unless otherwise specified.

Given that arbitrary two voltages to be compared with each other are voltages v1 and v2, “v1>v2” represents that the voltage v1 is higher than the voltage v2, “v1<v2” represents that the voltage v1 is lower than the voltage v2, and “v1=v2” represents that the voltage v1 and the voltage v2 are equal in value to each other. This is applicable also to other equations and expressions containing physical quantities other than voltage.

FIG. 1 is an overall configuration diagram of a load driving system SYS according to an embodiment of the present disclosure. The load driving system SYS includes, as principal constituent components, a switch device 10, an MCU (Micro Controller Unit) 20, and a temperature detection circuit 30. The MCU 20 is an example of an external control unit that controls operations of the switch device 10. The load driving system SYS is also equipped with resistors 41 and 42. A voltage source VS, a load LD and an output capacitor Cout are connected to the load driving system SYS. In this case, the load LD and the output capacitor Cout are regarded as elements outside the load driving system SYS, whereas the load LD and the output capacitor Cout may instead be construed as included in the component elements of the load driving system SYS. Likewise, the voltage source VS may be regarded as included in component elements of the load driving system SYS and also may be regarded as not included in component elements of the load driving system SYS.

The switch device 10 includes a power supply terminal VBB, an output terminal OUT, a ground terminal GND, a control input terminal IN, a current information output terminal SNS and a diagnostic terminal ST, as well as terminals CSB, SCLK, SI and SO. The power supply terminal VBB and the output terminal OUT may also be referred to as power input terminal and power output terminal, respectively.

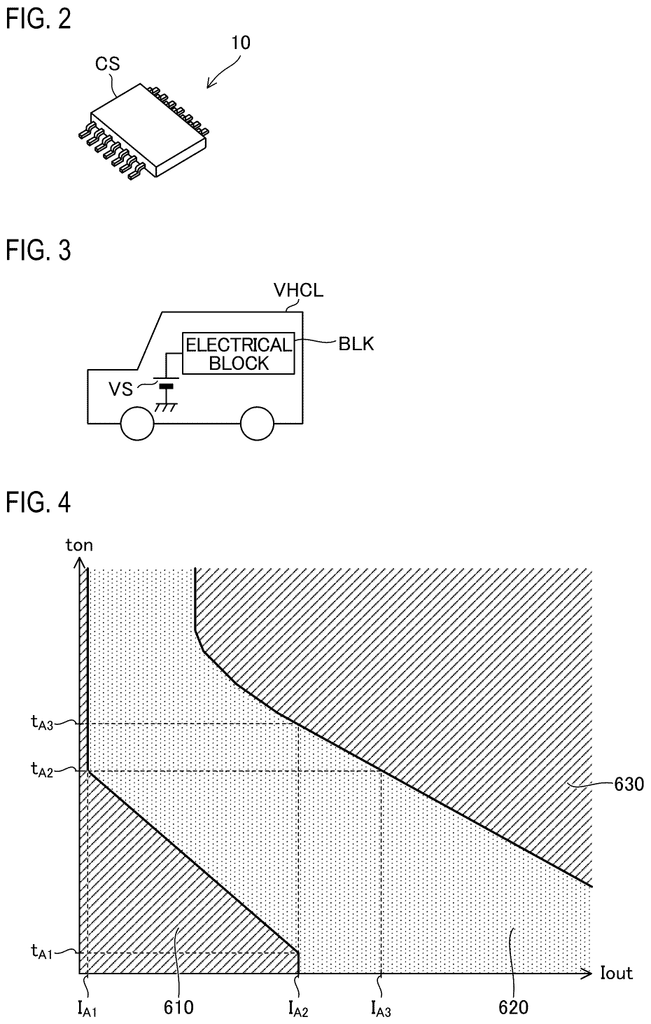

FIG. 2 is an appearance perspective view of the switch device 10. The switch device 10 is an electronic component which includes: a semiconductor chip having semiconductor integrated circuits formed on a semiconductor substrate; a package CS configured to house the semiconductor chip; and a plurality of external terminals exposed from the package CS to outside of the switch device 10. Sealing the semiconductor chip in the package CS formed from resin allows the switch device 10 to be formed up. It is noted that the number of external terminals of the switch device 10 and the type of the package CS of the switch device 10 as shown in FIG. 2 are only exemplifications and arbitrarily designable. Among the plurality of external terminals provided in the switch device 10, shown as a total of ten external terminals in FIG. 1 are the power supply terminal VBB, the output terminal OUT, the ground terminal GND, the control input terminal IN, the current information output terminal SNS and the diagnostic terminal ST, as well as the terminals CSB, SCLK, SI and SO; however, external terminals other than those may also be provided in the switch device 10. In addition, the power supply terminal VBB may also be given by two or more external terminals. This is also applicable to the output terminal OUT or the ground terminal GND.

The voltage source VS, which is connected to the ground and an input wiring W1, produces a power supply voltage Vbb being a positive DC voltage as referenced to the ground. The power supply voltage Vbb is applied to the input wiring W1. The input wiring W1 is a wiring which is provided outside the switch device 10 and which is connected to both the voltage source VS and the power supply terminal VBB. Therefore, the power supply voltage Vbb is applied to the power supply terminal VBB. A current supplied from the voltage source VS via the input wiring W1 to the power supply terminal VBB is referred to as input current Iin.

The output terminal OUT is connected to the load LD through an output wiring W2. The output capacitor Cout is connected in parallel with the load LD. A voltage at the output terminal OUT is referred to as output voltage Vout. Therefore, the output voltage Vout is applied to the output wiring W2. The output wiring W2 is a wiring which is provided outside the switch device 10 and which is connected to both the output terminal OUT and the load LD (in more detail, a wiring that connects the output terminal OUT with the parallel circuit of the load LD and the output capacitor Cout). A current supplied from the output terminal OUT via the output wiring W2 to the load LD (in more detail, the parallel circuit of the load LD and the output capacitor Cout) is referred to as output current Iout. That is, the load driving system SYS supplies the load LD with the output current Iout. The output current Iout is a drain current of a later-described output transistor M1. A first end of the load LD is connected to the output wiring W2, while a second end of the load LD is connected to the ground. A first end of the output capacitor Cout is connected to the output wiring W2, while a second end of the output capacitor Cout is connected to the ground. The load LD is an arbitrary load driven on the output voltage Vout serving as a power supply voltage.

The ground terminal GND is connected to the ground. The control input terminal IN, the current information output terminal SNS and the diagnostic terminal ST, as well as the terminals CSB, SCLK, SI and SO, are connected to the MCU 20.

The MCU 20 and the temperature detection circuit 30 are provided outside the switch device 10. The MCU 20, which is supplied with the power supply voltage VCC of a specified positive DC voltage value and connected to the ground, is driven on the power supply voltage VCC.

The temperature detection circuit 30, upon detecting a temperature Tmp in vicinity of the switch device 10, generates a temperature detection signal Tsns. The temperature detection signal Tsns is delivered from the temperature detection circuit 30 to the MCU 20. The temperature Tmp is a temperature at an object space outside the switch device 10 and in vicinity of the switch device 10; hereinafter, the temperature Tmp will be referred to as outside temperature Tmp. The object space is a space in which the input wiring W1 and the output wiring W2 are placed. The object space may instead be a space in which either one of the input wiring W1 and the output wiring W2 is placed. The temperature detection circuit 30 has a temperature measuring device (temperature measuring resistor, linear resistor, thermistor, or the like) placed in the object space, being enabled to detect the outside temperature Tmp by using the temperature measuring device. The temperature detection circuit 30 may otherwise be a semiconductor temperature sensor. The semiconductor temperature sensor has a silicon diode placed in the object space to detect the outside temperature Tmp by utilizing temperature characteristics of a forward voltage of the diode. Instead of the forward voltage of the diode, a base-emitter voltage of a bipolar transistor may be utilized to detect the outside temperature Tmp.

The temperature detection signal Tsns is a voltage signal representing an outside temperature Tmp (a voltage signal indicative of a detection value of the outside temperature Tmp). The temperature detection signal Tsns may be an analog voltage signal or a digital voltage signal. With either signal, a value of the outside temperature Tmp is specifically determined from a signal value of the temperature detection signal Tsns.

Referring to FIG. 3, it is assumed, in this embodiment, that the load driving system SYS is mounted on a vehicle VHCL such as an automobile. In this case, the voltage source VS may be a battery installed on the vehicle VHCL. The vehicle VHCL is equipped with an electrical block BLK containing various types of electrical components, where the constituent elements of the electrical block BLK include the load driving system SYS, the load LD and the output capacitor Cout as well as various wirings such as the input wiring W1 and the output wiring W2. Therefore, the above-described object space is a space within the vehicle VHCL. The load LD includes an ECU (Electronic Control Unit) as well as an actuator such as a motor driven and controlled by the ECU, an illuminating device, an air conditioner, and the like.

The switch device 10 has circuitry made up from semiconductor, and the circuitry is housed in the package CS. The circuitry made up from semiconductor in the switch device 10 includes an output transistor M1, a controller 11, a driver 12, a charge pump circuit 13, a current detection circuit 14, an abnormality detection circuit 15, an error output circuit 16, an internal power supply circuit 17, and Schmitt buffers (Schmitt triggers) SM1 to SM4.

The output transistor M1 is given by an N-channel MOSFET. The drain of the output transistor M1 is connected to the power supply terminal VBB, and the source of the output transistor M1 is connected to the output terminal OUT. A drain current of the output transistor M1 is the output current Iout. An active clamper (not shown) configured to protect the output transistor M1 from a counter electromotive voltage arising from an inductive load may be provided between drain and gate of the output transistor M1.

A control signal Sin is supplied from the MCU 20 to the control input terminal IN. The control signal Sin is a binary signal with signal levels of high level and low level. The high level in the control signal Sin being an active level (on-command level), a high-level control signal Sin is a signal by which the MCU 20 instructs the switch device 10 and the controller 11 to set the output transistor M1 to an on state. The low level in the control signal Sin being a non-active level (off-command level), a low-level control signal Sin is a signal by which the MCU 20 instructs the switch device 10 and the controller 11 to set the output transistor M1 to an off state. A control signal Sin supplied to the control input terminal IN is inputted to the Schmitt buffer SM1. The Schmitt buffer SM1 shapes a waveform of the control signal Sin inputted to the Schmitt buffer SM1 itself, delivering the waveform-shaped control signal Sin to the controller 11.

The controller 11, based on a waveform-shaped control signal Sin, generates a drive control signal Sdrv, delivering it to the driver 12. The control signal Sin in description of operations principally performed by the controller 11 is a waveform-shaped control signal Sin. However, there is no substantial difference in level of the control signal Sin before and after the waveform shaping. Therefore, presence or absence of waveform shaping in the control signal Sin will not be taken into consideration hereinafter. The drive control signal Sdrv is also a binary signal with signal levels of high level and low level, like the control signal Sin. The controller 11, in principle, outputs a high-level drive control signal Sdrv during high-level periods of the control signal Sin supplied to itself, and outputs a low-level drive control signal Sdrv during low-level periods of the control signal Sin supplied to itself. The high level in the drive control signal Sdrv being an active level, the high-level drive control signal Sdrv is a signal by which the controller 11 instructs the driver 12 to set the output transistor M1 to an on state. The low level in the drive control signal Sdrv being a non-active level, a low-level drive control signal Sdrv is a signal by which the controller 11 instructs the driver 12 to set the output transistor M1 to an off state.

The driver 12 is connected to the gate and the source of the output transistor M1. During a high-level period of the drive control signal Sdrv, the driver 12 supplies the gate of the output transistor M1 with a drive voltage Vcp supplied from the charge pump circuit 13, so that the output transistor M1 is set to an on state. During a low-level period of the drive control signal Sdrv, the driver 12 supplies the gate of the output transistor M1 with a voltage at the source of the output transistor M1 or a ground voltage, so that the output transistor M1 is set to an off state.

The charge pump circuit 13, which is connected to the power supply terminal VBB, boosts the power supply voltage Vbb under control by the controller 11 so as to generate a drive voltage Vcp higher than the power supply voltage Vbb. The drive voltage Vcp is supplied to the driver 12. A difference between the drive voltage Vcp and the power supply voltage Vbb is larger than a gate threshold voltage of the output transistor M1. In addition, the configuration may be modified such that the output transistor M1 is given by a P-channel MOSFET, where adopting this modification eliminates the need for the charge pump circuit 13.

The current detection circuit 14 detects a drain current of the output transistor M1, i.e., detects an output current Iout flowing through the output transistor M1. The current detection circuit 14 delivers a current detection signal Isns, which is indicative of a detection result of the output current Iout, to the abnormality detection circuit 15. The current detection circuit 14, instead of the abnormality detection circuit 15 or in addition to the abnormality detection circuit 15, may deliver the current detection signal Isns to the controller 11. The current detection signal Isns may be an analog voltage signal indicative of a value of the output current Iout, or may be a digital signal indicating a value of the output current Iout by digital value. In either case, a value of the output current Iout is represented by the current detection signal Isns. The current detection circuit 14 delivers an analog voltage signal Isns2, which is indicative of a detection result of the output current Iout, to the MCU 20 through the current information output terminal SNS. A pull-down resistor 42 is connected between the ground and a wiring 44, by which the MCU 20 and the current information output terminal SNS are connected to each other, so that a voltage signal Isns2 is transmitted to the MCU 20 through the wiring 44. The voltage signal Isns2 may be like or unlike the current detection signal Isns. In the switch device 10, the function of outputting the voltage signal Isns2 and the current information output terminal SNS may be omitted.

The abnormality detection circuit 15 detects a plurality of types of abnormalities that can occur to the switch device 10. Included in the plurality of types of abnormalities are: overcurrent abnormalities such that an excessively large current flows through the output transistor M1; temperature abnormalities such that a temperature of the output transistor M1 or a temperature of a particular site within the switch device 10 becomes equal to or higher than a specified protective temperature; low voltage abnormalities such that a voltage supplied to the power supply terminal VBB becomes equal to or lower than a low-voltage threshold value; open abnormalities such that the output terminal OUT comes to an open state; and the like. An overcurrent abnormality is detected on a basis of a current detection signal Isns supplied from the current detection circuit 14. The abnormality detection circuit 15 delivers to the controller 11 a signal indicating whether or not any abnormality has been detected. The abnormality detection circuit 15 is enabled to deliver, to the controller 11, signals indicating whether or not any abnormality has been detected, in correspondence to types of detectable abnormalities, respectively. An overcurrent detection signal Sdet is among signals that are delivered from the abnormality detection circuit 15 to the controller 11. When an abnormality is detected by the abnormality detection circuit 15, the controller 11 executes an abnormality counter operation. One type of the abnormality counter operation is a shutdown operation in which the drive control signal Sdrv is held low level to keep the output transistor M1 at an off state, independent of the control signal Sin (therefore, even though the control signal Sin has high level).

The error output circuit 16 is a circuit operable to transmit a signal, which is indicative that an abnormality has been detected, to the MCU 20 when any abnormality is detected by the abnormality detection circuit 15. More specifically, the error output circuit 16 includes a transistor 16a of open drain configuration. The transistor 16a is an N-channel MOSFET. A drain of the transistor 16a is connected to the diagnostic terminal ST, and a source of the transistor 16a is connected to the ground. A pull-up resistor 41 is connected between a wiring 43, by which the MCU 20 and the diagnostic terminal ST are connected to each other, and a node to which the power supply voltage VCC is applied. The controller 11 controls the gate voltage of the transistor 16a to set the transistor 16a to on or off. When no abnormality has been detected by the abnormality detection circuit 15, the controller 11 sets the transistor 16a off, when an arbitrary abnormality has been detected by the abnormality detection circuit 15, the controller 11 sets the transistor 16a on. A voltage of the wiring 43 substantially equals the power supply voltage VCC while the transistor 16a is off and substantially equals the ground voltage while the transistor 16a is on. Therefore, the MCU 20 is enabled to recognize, based on the voltage of the wiring 43, whether or not any abnormality has been detected by the switch device 10.

The internal power supply circuit 17, which is connected to the power supply terminal VBB, steps down the power supply voltage Vbb by referencing the ground voltage to generate an internal power supply voltage Vreg. The internal power supply voltage Vreg has a specified positive DC voltage value. Individual circuits within the switch device 10 can be driven on a basis of the internal power supply voltage Vreg by referencing the ground potential.

The controller 11 is connected to the MCU 20 via a communication terminal group CTG including the terminals CSB, SCLK, SI and SO, thus capable of performing two-way communications with the MCU 20 by using the communication terminal group CTG. In addition, communication between the controller 11 and the MCU 20 and communication between the switch device 10 and the MCU 20 are synonymous with each other. Although communication between the switch device 10 and the MCU 20 may be parallel communication, it is assumed in this embodiment that the communication between the switch device 10 and the MCU 20 is serial communication, with SPI (Serial Peripheral Interface) used as an interface for serial communication. The terminal CSB is a chip select terminal for reception of a chip select signal derived from the MCU 20. The terminal SCLK is a clock input terminal for reception of a clock signal derived from the MCU 20. The terminal SI is a data input terminal for reception of an input data signal derived from the MCU 20. The terminal SO is a data output terminal for output of an output data signal toward the MCU 20. The switch device 10 is equipped with the Schmitt buffer SM2 for waveform shaping of a chip select signal received by the terminal CSB, the Schmitt buffer SM3 for waveform shaping of a clock signal received by the terminal SCLK, and the Schmitt buffer SM4 for waveform shaping of an input data signal received by the terminal SI, where the chip select signal, the clock signal and the input data signal, each after subjected to waveform shaping, are inputted to the controller 11. The controller 11 supplies the MCU 20 with an output data signal via the terminal SO.

A communication interface (not shown) that performs transmission and reception of signals according to the SPI is contained in the controller 11. It may appropriately be considered that a communication interface is provided between the communication terminal group CTG and the controller 11. Furthermore, the interface of serial communication between the switch device 10 and the MCU 20 is not limited to SPI and, therefore, I²C (Inter-Integrated Circuit) or Microwire interface is also usable as an example.

The MCU 20 recognizes an outside temperature Tmp on a basis of a temperature detection signal Tsns. The MCU 20 transmits to the switch device 10 an outside temperature signal (outside temperature information) representing the outside temperature Tmp recognized by the MCU 20 itself. The outside temperature signal is received by the controller 11 via the communication terminal group CTG. The MCU 20 is enabled to periodically transmit to the switch device 10 an outside temperature signal representing a latest outside temperature Tmp based on a latest temperature detection signal Tsns. An outside temperature Tmp represented by a latest outside temperature signal received by the controller 11 is, in particular, referred to as a reference outside temperature Tmp. Given that a delay from detection of an outside temperature Tmp by the temperature detection circuit 30 until reception of an outside temperature signal indicative of the detection result by the controller 11 is short enough to be ignored, the reference outside temperature Tmp is equal to the outside temperature Tmp detected by the temperature detection circuit 30 at any arbitrary time point.

The MCU 20 is further enabled to transmit various types of command signals to the switch device 10. A command signal is received by the controller 11 via the communication terminal group CTG. The controller 11 is enabled to perform operation and setting assigned by the command signal.

The wirings W1 and W2 are electrical wiring members formed by applying insulating coating to copper wires, individually. In the load driving system SYS, it is assumed that a relatively large current (e.g., of several amperes) flows as an output current Iout in a steady state, and moreover that, although as an inrush current in short time, an even larger current (e.g., of several tens of amperes) than in the steady state flows as an output current Iout at start-up of the load driving system SYS. For this reason, there is a need for designing and preparing the wirings W1 and W2 having such diameters as to allow for safety use. Indeed sufficiently increasing the diameters of the wirings W1 and W2 eliminates safety-related fears with a sufficient margin, but increases in diameters would incur increases in cost and size. It is desired that with safety ensured, the wirings W1 and W2 be made as small in diameter as possible.

Hereinafter, for convenience' sake of explanation, the input wiring W1 or the output wiring W2 will be referred to as an object wiring (target wiring). It may also be construed that the input wiring W1 and the output wiring W2 are designated by the object wiring. The output current Iout flows through the object wiring. The switch device 10 has a function of protecting the object wiring from excessive heat generation due to excessive current. This function is equivalent to a function of the so-called electronic fuse.

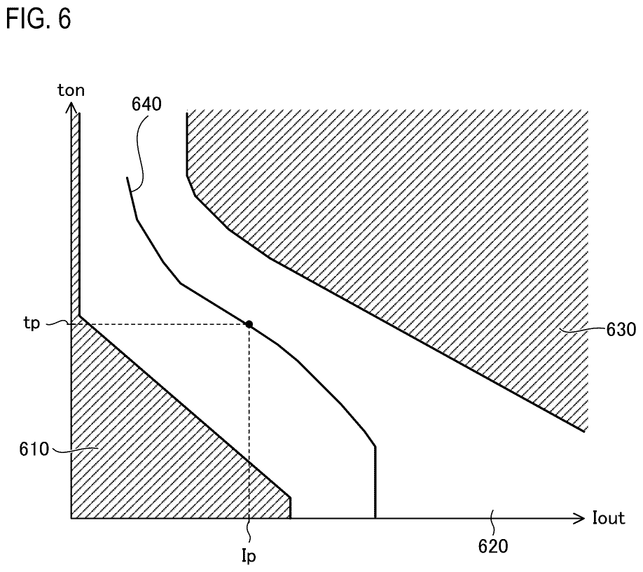

Referring to FIG. 4, here are described characteristics of the object wiring. FIG. 4 charts characteristics of the object wiring as well as an operating region of the output transistor M1 that is defined in terms of its relationship with the object wiring. A time during which the output transistor M1 is continuously held at on state (a time length during which the output transistor M1 is continued to be held at on state) will be referred to as continuous on time ton. The operating region of the output transistor M1 is divided into three regions 610, 620 and 630 from a viewpoint of a relationship with characteristics of the object wiring. The regions 610 and 630 in FIG. 4 are depicted by a first hatched region and a second hatched region, respectively (this is applicable also to later-described FIG. 6 and others). The region 620 is depicted by a dotted region in FIG. 4. Current values I_{A1} to I_{A3} shown in FIG. 4 are three specified current values satisfying a relational expression that “0<I_{A1}<I_{A3}”. Times t_{A1} to t_{A3} shown in FIG. 4 are three specified times (time lengths) satisfying that “0<t_{A1}<t_{A2}<t_{A3}”.

The region 610 is a normal operating region. The region 620 is a protection-recommended region. The region 630 is a use-prohibited region. In the chart in which the output current Iout is represented by the horizontal axis while the continuous on time ton is represented by the vertical axis, the protection-recommended region 620 is located between the normal operating region 610 and the use-prohibited region 630. The normal operating region 610 is a region in which the object wiring is used safely. In the load driving system SYS, the output transistor M1 is driven within the normal operating region 610 unless any fault or the like arises. The use-prohibited region 630 is a region in which the object wiring cannot be used safely, so that use of the object wiring in the use-prohibited region 630 (in other words, use of the output transistor M1 in the use-prohibited region 630) is prohibited in terms of safety securement. Therefore, when the output transistor M1 has come into operation in the protection-recommended region 620 for some reason, the output transistor M1 should be shut down before reaching the use-prohibited region 630. Shutting down the output transistor M1 means switching the output transistor M1 from on to off state and holding it at off state.

A region in which the output current Iout has values lower than a specified current value I_{A1} belongs to the normal operating region 610. That is, given a value of the output current Iout lower than the current value I_{A1}, the object wiring can be used safely even with the continuous on time ton long enough. As is designed for the load driving system SYS and the load LD, after the output transistor M1 is switched from off to on, the output current Iout comes to have a value lower than the current value I_{A1} in the steady state unless some malfunction or the like arises.

A region in which the value of the output current Iout falls within a range from the current value I_{A1} to the current value I_{A2} partly belongs to the normal operating region 610. The current value I_{A2} is several times to several tens times larger than the current value I_{A1}, as an example. Immediately after the output transistor M1 is switched from off to on, and before it reaches the steady state, an output current Iout larger than in the steady state flows transiently as an inrush current due to charging of the output capacitor Cout or the like. The load driving system SYS and the load LD are so designed that the inrush current falls within the normal operating region 610.

A region in which the value of the output current Iout equals the current value I_{A1} and moreover the continuous on time ton is not more than a specified time t_{A2} belongs to the normal operating region 610. Accordingly, under a condition that the value of the output current Iout equals the current value I_{A1}, a length of the continuous on time ton, as far as being not more than the specified time t_{A2}, makes it possible to use the object wiring safely.

A region in which the value of the output current Iout equals the current value I_{A3} and moreover the continuous on time ton is not less than the specified time t_{A2} belongs to the use-prohibited region 630. Accordingly, under a condition that the value of the output current Iout equals the current value I_{A3}, the controller 11 shuts down the output transistor M1 before the continuous on time ton reaches the specified time t_{A2}. A region in which the value of the output current Iout equals the current value I_{A3} and moreover the continuous on time ton is less than the specified time t_{A2} belongs to the protection-recommended region 620.

A region in which the value of the output current Iout equals the current value I_{A2} and moreover the continuous on time ton is not more than the specified time t_{A1} belongs to the normal operating region 610. A region in which the value of the output current Iout equals the current value I_{A2} and moreover the continuous on time ton is not less than the specified time t_{A3} belongs to the use-prohibited region 630. A region in which the value of the output current Iout equals the current value I_{A2} and moreover which satisfies that “t_{A1}<ton<t_{A3}” belongs to the protection-recommended region 620.

The normal operating region 610, the protection-recommended region 620 and the use-prohibited region 630 have been described above with attention given to the three current values I_{A1} to I_{A3} and the three times t_{A1} to t_{A3} for the sake of concretized explanation. However, in actuality, under a condition that the value of the output current Iout falls within a range from the current value I_{A1} to the current value I_{A2}, the continuous on time ton belonging to the normal operating region 610 continuously decreases with increasing output current Iout. Similarly, the continuous on time ton belonging to the use-prohibited region 630 also continuously decreases with increasing output current Iout. In either case, it is essential to shut down the output transistor M1 within the protection-recommended region 620.

In cooperation with the current detection circuit 14 and the abnormality detection circuit 15, the controller 11 is enabled to execute an overcurrent protecting operation a, which contributes to safety securement of the object wiring. The overcurrent protecting operation a is an operation the execution of which is decided under a condition that the output transistor M1 has been set to on state; therefore, the output transistor M1 is at on state immediately before execution of the overcurrent protecting operation a. The overcurrent protecting operation a is a shutdown operation in which, without depending on the control signal Sin (therefore, even though the control signal Sin is at high level), the output transistor M1 is switched from on to off state and thereafter maintained at off state. In addition, the overcurrent protecting operation a also has a role of protecting the switch device 10 itself from excessive heat generation.

Based on the current detection signal Isns, the abnormality detection circuit 15 continuously monitors whether or not an overcurrent condition is satisfied; then the abnormality detection circuit 15 delivers to the controller 11 an overcurrent detection signal Sdet based on satisfaction or not of the overcurrent condition. The overcurrent detection signal Sdet, being a binary signal having a value of “1” or “0”, normally has a value of “0”. When the overcurrent condition is satisfied, the abnormality detection circuit 15 delivers the overcurrent detection signal Sdet of “1” to the controller 11. While the overcurrent detection signal Sdet has the value of “0”, the controller 11 executes no overcurrent protecting operation a. In response to a switchover of the value of the overcurrent detection signal Sdet from “0” to “1”, the controller 11 executes the overcurrent protecting operation a.

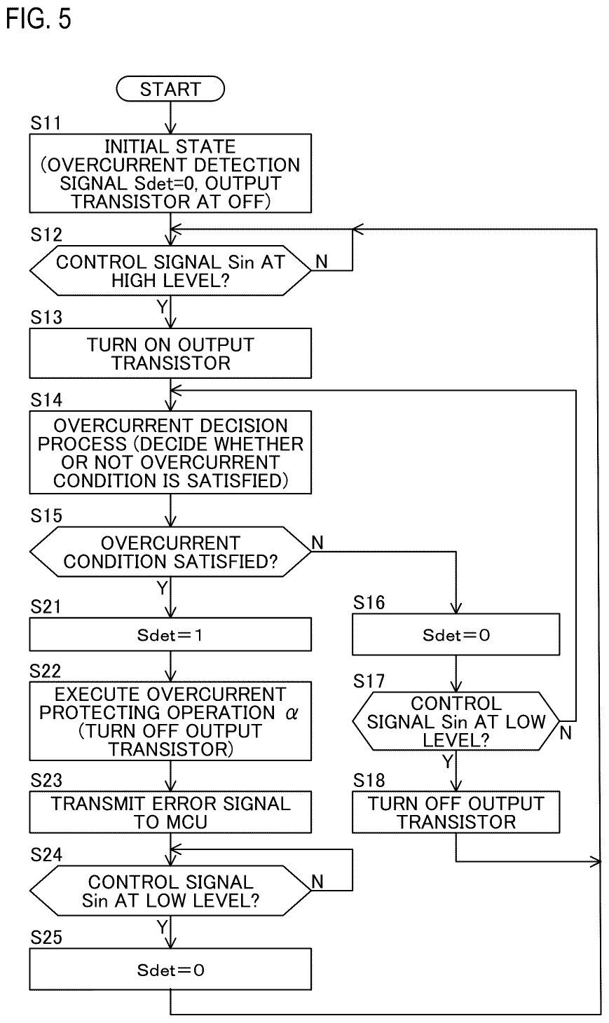

FIG. 5 shows an operation flowchart of the switch device 10. For explanation's sake, it is assumed that nothing, but overcurrent abnormalities related to the overcurrent protecting operation a arises in this case. As the switch device 10 is started up, the switch device 10 comes to an initial state at step S11. In the initial state of the switch device 10, the overcurrent detection signal Sdet has a value of “0” and the drive control signal Sdrv is set to low level, hence the output transistor M1 being off. At step S12 subsequent to step S11, the controller 11 checks whether or not the control signal Sin is at high level, where as long as the control signal Sin is at high level (Y at step S12), the controller 11 exerts a transition to step S13. At step S13, the controller 11 changes over the drive control signal Sdrv from low to high level, thereby changing over the output transistor M1 from off to on state. Thereafter, the processing moves on to step S14.

At step S14, the abnormality detection circuit 15 executes an overcurrent decision process. In the overcurrent decision process, based on the current detection signal Isns, the abnormality detection circuit 15 decides whether or not the overcurrent condition is satisfied. At step S15 subsequent to step S14, the decision result as to satisfaction or not of the overcurrent condition is checked. With the overcurrent condition satisfied (Y at step S15), the processing moves on to step S21; or with the overcurrent condition not satisfied (N at step S15), the processing moves on to step S16.

At step S16, the abnormality detection circuit 15 holds the value of the overcurrent detection signal Sdet still at “0”. Thereafter, the processing moves on to step S17. At step S17, the controller 11 checks whether or not the control signal Sin is at low level. With the control signal Sin at low level (Y at step S17), the processing moves on to step S18; or with the control signal Sin at high level (N at step S17), the processing returns to step S14. At step S18, the controller 11 changes over the drive control signal Sdrv from high to low level, thereby changing over the output transistor M1 from on to off state. Thereafter, the processing returns to step S12.

At step S21, the abnormality detection circuit 15 changes over the value of the overcurrent detection signal Sdet from “0” to “1”. Subsequent to step S21, the processing moves on to step S22. At step S22, the controller 11, upon receiving the overcurrent detection signal Sdet of “1”, executes the overcurrent protecting operation a. As a result, the output transistor M1 is changed over from on to off state, and thereafter the output transistor M1 is held at off state until returning again to step S13. Subsequent to step S22, the processing moves on to step S23. At step S23, the controller 11 transmits an error signal to the MCU 20 by using the error output circuit 16. The transmission of an error signal is equivalent to making the transistor 16a changed over from off to on, thereby making the level of the wiring 43 changed over from high to low level. In addition, at step S23, error flag data indicative that an overcurrent abnormality due to satisfaction of the overcurrent condition has been detected is stored in the controller 11. The MCU 20, upon receiving the error signal, reads out the error flag data by utilizing SPI communication, thereby enabled to recognize that the overcurrent abnormality due to satisfaction of the overcurrent condition has been detected.

Subsequent to step S23, the processing moves on to step S24. At step S24, the controller 11 checks whether or not the control signal Sin is at low level. With the control signal Sin at low level (Y at step S24), the processing moves on to step S25; or with the control signal Sin at high level (N at step S24), the process of step S24 is repeated. At step S25, the value of the overcurrent detection signal Sdet is initialized to “0” by cooperation of the controller 11 and the abnormality detection circuit 15; thereafter, the processing returns to step S12.

As will be understood from the operation flowchart of FIG. 5, when the output transistor M1 is once changed over from on to off state by the overcurrent protecting operation a due to satisfaction of the overcurrent condition, the output transistor M1 is latched at off state. The latch in off state of the output transistor M1 is canceled by the control signal Sin being once returned to low level. Thereafter, the control signal Sin is set to high level once again, causing the output transistor M1 to be changed over from off to on state.

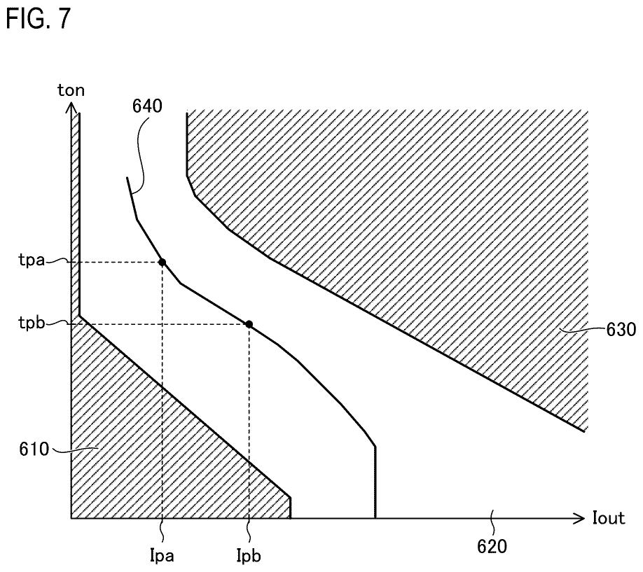

The overcurrent condition is now explained with reference to FIG. 6. In FIG. 6, although the normal operating region 610 and the use-prohibited region 630 are expressed by hatched regions, such dotted depiction as seen in FIG. 4 is not added to the protection-recommended region 620, for prevention of depictive complication (this is applicable also to later-described FIG. 7 and others). The overcurrent condition is satisfied when a state with the output current Iout having a protective current value Ip has lasted for a protection activating time tp. In the chart of FIG. 6, a point corresponding to the event that the state with the output current Iout having the protective current value Ip lasts for the protection activating time tp exists within the protection-recommended region 620. Although it seems in FIG. 6 that the protective current value Ip has a single value and the protection activating time tp has a single time, yet actually the protection activating time tp is a function having the protective current value Ip as an independent variable. A polygonal line 640 in FIG. 6 represents a graph of the function (this is applicable also to later-described FIG. 7). Accordingly, the protection activating time tp varies with variations in the protective current value Ip. In this aspect, the protection activating time tp decreases with increasing protective current value Ip, while the protection activating time tp increases with decreasing protective current value Ip.

Consequently, as shown in FIG. 7, the overcurrent condition is satisfied when a state with the output current Iout having a protective current value Ipa has lasted for a protection activating time tpa, or when a state with the output current Iout having a protective current value Ipb has lasted for a protection activating time tpb. In this case, it holds that “Ipa<Ipb” and “tpa>tpb”. The abnormality detection circuit 15 includes a timer and based on the current detection signal Isns and by using the timer, decides whether or not the overcurrent condition is satisfied. In addition, hereinafter, symbol “Iout” may be used as a symbol indicating a value of the output current Iout; “Iout” as seen in any equation or expression given hereinbelow indicates a value of the output current Iout. Accordingly, for example, “Iout=Ipa” means that the output current Iout has a protective current value Ipa (i.e., the value of the output current Iout equals the protective current value Ipa); “Iout>Ipa” means that the value of the output current Iout is larger than the protective current value Ipa.

In a case where a state of “Iout=Ipa” has lasted for a time (tpa−Δt) and, subsequently, a state of “Iout>Ipa” has lasted for a time Δt, the overcurrent condition is satisfied as well. Similarly, in another case where a state of “Iout=Ipb” has lasted for a time (tpb−Δt) and, subsequently, a state of “Iout>Ipb” has lasted for a time Δt, the overcurrent condition is satisfied as well. The time “tpa−Δt” indicates a time duration which is shorter than the protection activating time tpa by the time Δt. The time (tpb−Δt) indicates a time duration which is shorter than the protection activating time tpb by the time Δt.

A relationship between the protective current value Ip and the protection activating time tp is referred to as overcurrent protection characteristic. Use of a proper overcurrent protection characteristic makes it possible to use the object wiring with safety, so that the object wiring can be protected from unexpected events.

However, proper protection of the object wiring from excessive heat generation involves considerations for the outside temperature Tmp. Therefore, in the switch device 10, the relationship between the protective current value Ip and the protection activating time tp (overcurrent protection characteristic) is varied in response to the reference outside temperature Tmp. As a consequence, in the switch device 10, the protection activating time tp is given as a function which has not only the protective current value Ip as an independent variable but also the reference outside temperature Tmp as an independent variable. The reference outside temperature Tmp, as described above, is an outside temperature Tmp represented by a latest outside temperature signal received by the controller 11. A function of setting the overcurrent protection characteristic variable in response to the reference outside temperature Tmp indeed may be provided in the abnormality detection circuit 15 but is provided in the controller 11 in this case, with an assumption that the overcurrent protection characteristic set in the controller 11 is utilized by the abnormality detection circuit 15.

The controller 11 operates such that the protection activating time tp corresponding to one protective current value Ip is decreased with increasing reference outside temperature Tmp, and the protection activating time tp corresponding to one protective current value Ip is increased with decreasing reference outside temperature Tmp.

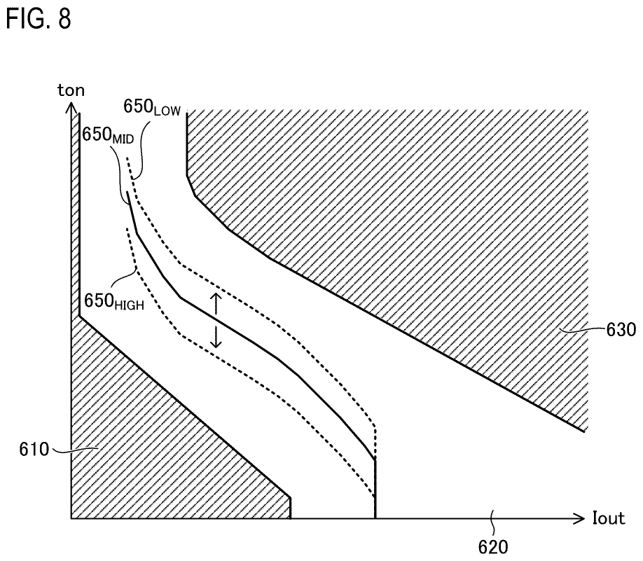

Referring to FIG. 8, a characteristic 650_{MID} is an overcurrent protection characteristic resulting when the reference outside temperature Tmp equals a specified intermediate temperature T_{MID}; a characteristic 650_{HIGH} is an overcurrent protection characteristic resulting when the reference outside temperature Tmp equals a specified high temperature T_{HIGH} higher than the intermediate temperature T_{M}ID; and a characteristic 650_{LOW} is an overcurrent protection characteristic resulting when the reference outside temperature Tmp equals a specified low temperature T_{LOW} lower than the intermediate temperature T_{MID}. Increases in the reference outside temperature Tmp cause the overcurrent protection characteristic to be shifted in such a direction as to decrease the protection activating time tp (shifted downward in the graph of FIG. 8). Decreases in the reference outside temperature Tmp cause the overcurrent protection characteristic to be shifted in such a direction as to increase the protection activating time tp (shifted upward in the graph of FIG. 8).

Further discussed is a first reference mode in which information as to the output current Iout detected by the switch device 10 is received by the MCU 20, followed by the MCU 20 itself deciding presence or absence of an overcurrent by using the timer. In this first reference mode, the MCU 20 sets an overcurrent protection characteristic on a basis of a diameter of the object wiring, measures a time duration lasting for the output current Iout to become excessive, and instructs the switch device 10 to shut down the output transistor M1 as required. Unfortunately, with this first reference mode, the MCU 20 is burdened to more extent, and worsened in terms of quick response for shutdown in proportion to a need for signal exchange between the switch device 10 and the MCU 20. Also with the first reference mode, in a case where the MCU 20 controls operations of multiple switch devices 10, there can arise, in the MCU 20, a lack of communication terminals for reception of current information, or the MCU 20 is burdened with excessive processing loads, leading to a processing difficulty.

In contrast, as in the present embodiment, disadvantages involved in the first reference mode are solved by the function (hereinafter, referred to as self-protecting function) in which under monitoring of the output current Iout on the switch device 10 side, the output transistor M1 is shut down, as required, based on the overcurrent protection characteristic without depending on any command from the MCU 20. In this case, properly setting the overcurrent protection characteristic in response to the diameter of the object wiring makes it possible to optimize the diameter of the object wiring while ensuring safety of the object wiring. However, with a second reference mode featuring merely in installing the self-protecting function on the switch device side, there is a difficulty in properly adjusting the overcurrent protection characteristic due to any unknown outside temperature Tmp, resultantly leading to another difficulty in reducing the diameter of the object wiring.

In view of the above-described circumstances, the load driving system SYS according to this embodiment transmits the outside temperature Tmp to the switch device 10. Then, in the switch device 10, the overcurrent protection characteristic is set dynamically in consideration of the outside temperature Tmp. As a consequence, the overcurrent protection characteristic can be adjusted properly in response to the outside temperature Tmp. The adjustment of the overcurrent protection characteristic leads to a reduction of a margin to be secured in diameter design of the object wiring, hence leading to a reduction of the diameter itself of the object wiring. The reduction of the diameter of the object wiring leads to weight reduction of vehicles VHCL, hence leading to increases in range distance of vehicles VHCL.

Hereinbelow, some specific operation examples, configuration examples, application techniques, modification techniques, and the like in association with the load driving system SYS and the switch device 10 will be described among a plurality of practical examples. Contents described above in the present embodiment are applied to the following individual practical examples unless otherwise specified and unless any contradictions are involved. In each practical example, when there is any contradiction to the above-described contents, priority may be given to description of each practical example. Furthermore, unless any contradictions are involved, contents described in any arbitrary practical example out of the plural practical examples given below may be applied to any other arbitrary practical examples (i.e., arbitrary two or more practical examples among the plural practical examples may be combined together).

In addition, each time a latest outside temperature signal derived from the MCU 20 is received by the switch device 10, the reference outside temperature Tmp recognized by the switch device 10 is updated. However, it is assumed hereinafter that the reference outside temperature Tmp is invariable or fixed during periods in which a decision as to whether the overcurrent condition is satisfied or not proceeds.

### First Practical Example

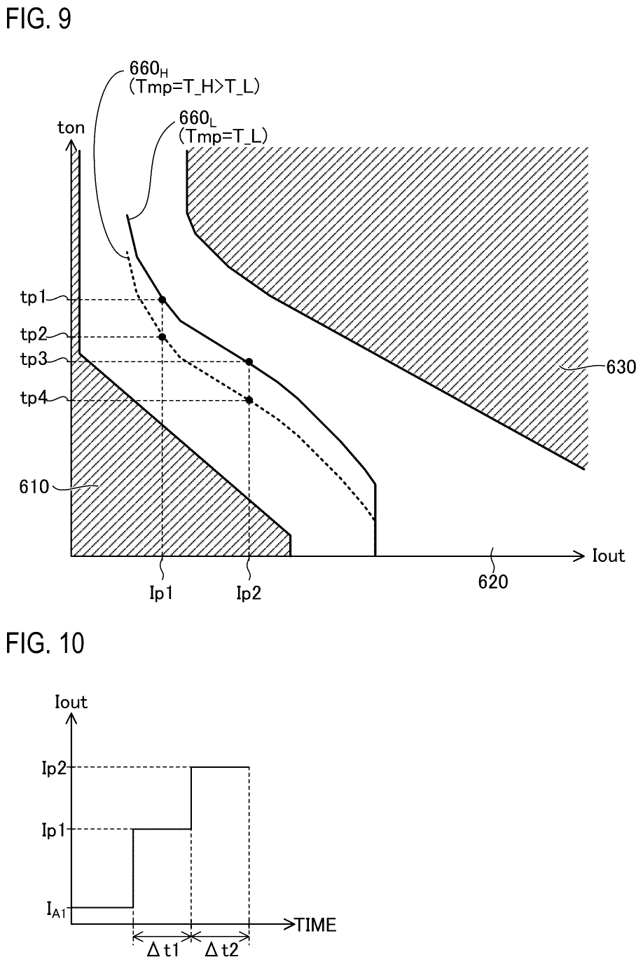

A first practical example will be described. FIG. 9 is referenced. In FIG. 9, a characteristic 660_{L} is an overcurrent protection characteristic resulting when the reference outside temperature Tmp equals a specified low-side temperature T_L, and a characteristic 660_{H} is an overcurrent protection characteristic resulting when the reference outside temperature Tmp equals a specified high-side temperature T_H. The high-side temperature T_H is higher than the low-side temperature T_L. The low-side temperature T_L and the high-side temperature T_H may be the above-described intermediate temperature T_{MID} and high temperature T_{HIGH}, respectively, in which case the characteristics 660_{L} and 660_{H} agree with the characteristics 650_{MID} and 650_{HIGH}, respectively, of FIG. 8. Instead, the low-side temperature T_L and the high-side temperature T_H may be the above-described low temperature T_{L}ow and high temperature T_{HIGH}, respectively, in which case the characteristics 660_{L} and 660_{H} agree with the characteristics 650_{LOW} and 650_{HIGH}, respectively, of FIG. 8. Instead, the low-side temperature T_L and the high-side temperature T_H may be the above-described low temperature T_{LOW} and intermediate temperature T_{MID}, respectively, in which case the characteristics 660_{L} and 660_{H} agree with the characteristics 650_{LOW} and 650_{MID}, respectively, of FIG. 8.

Current values Ip1 and Ip2 are two examples (first and second protective current values) of the protective current value Ip, where the current value Ip2 is larger than the current value Ip1. For instance, the current values Ip1 and Ip2 are 20 A (amperes) and 40 A, respectively. Times tp1 and tp3 are two examples (first and third protection activating times) of the protection activating time tp resulting when the reference outside temperature Tmp equals the low-side temperature T_L. Times tp2 and tp4 are two examples (second and fourth protection activating times) of the protection activating time tp resulting when the reference outside temperature Tmp equals the high-side temperature T_H. Under these circumstances, expressions “tp1>tp2”, “tp3>tp4”, “tp1>tp3” and “tp2>tp4” hold. Although “tp2>tp3” is seen in FIG. 9, any one of expressions “tp2>tp3”, “tp2=tp3”, and “tp2<tp3” holds depending on a difference between the current values Ip1 and Ip2 and a difference between the temperatures T_L and T_H.

With the reference outside temperature Tmp equal to the low-side temperature T_L, when the output current Iout has continued a state of having the current value Ip1 for the time tp1, the abnormality detection circuit 15, deciding that the overcurrent condition is satisfied, delivers an overcurrent detection signal Sdet of “1” to the controller 11. With the reference outside temperature Tmp equal to the high-side temperature T_H, when the output current Iout has continued a state of having the current value Ip1 for the time tp2, the abnormality detection circuit 15, deciding that the overcurrent condition is satisfied, delivers an overcurrent detection signal Sdet of “1” to the controller 11. It is noted that the state of the output current Iout having the current value Ip1 is a concept including not only a state in which the value of the output current Iout completely equals the current value Ip1 but also a state in which the value of the output current Iout is slightly larger than the current value Ip1.

With the reference outside temperature Tmp equal to the low-side temperature T_L, when the output current Iout has continued a state of having the current value Ip2 for the time tp3, the abnormality detection circuit 15, deciding that the overcurrent condition is satisfied, delivers an overcurrent detection signal Sdet of “1” to the controller 11. With the reference outside temperature Tmp equal to the high-side temperature T_H, when the output current Iout has continued a state of having the current value Ip2 for the time tp4, the abnormality detection circuit 15, deciding that the overcurrent condition is satisfied, delivers an overcurrent detection signal Sdet of “1” to the controller 11. It is noted that the state of the output current Iout having the current value Ip2 is a concept including not only a state in which the value of the output current Iout completely equals the current value Ip2 but also a state in which the value of the output current Iout is slightly larger than the current value Ip2.

The controller 11 executes the foregoing overcurrent protecting operation a in response to a reception of the overcurrent detection signal Sdet of “1” from the abnormality detection circuit 15.

In a comparison between the low-side temperature T_L and the high-side temperature T_H, it holds that “tp1>tp2” and “tp3>tp4”. Also, assuming that the reference outside temperature Tmp equals the low-side temperature T_L, since “Ip1<Ip2”, it holds that “tp1>tp3”. Similarly, assuming that the reference outside temperature Tmp equals the high-side temperature T_H, since “Ip1<Ip2”, it holds that “tp2>tp4”.

In addition, in a case where the output current Iout has values varying within a range not less than the foregoing current value I_{A1} (see FIG. 4), after specifically determining a maximum value of the output current Iout during a varying period of the output current Iout, and assuming that the output current Iout continues having the maximum value during the varying period, the abnormality detection circuit 15 may decide whether or not the overcurrent condition is satisfied. As a result of this, safety of the object wiring is ensured. For example, it is assumed, as shown in FIG. 10, that the value of the output current Iout, after abruptly increasing from less than the current value I_{A1} to the current value Ip1, is held at the current value Ip1 for a time Δt1, thereafter increasing to the current value Ip2 and being held at the current value Ip2 for a time Δt2. In this case, since the maximum value of the output current Iout during the varying period of the output current Iout is the current value Ip2, the abnormality detection circuit 15 may decide whether or not the overcurrent condition is satisfied, by assuming that the output current Iout continues having the current value Ip2 for the varying period. Then, given that a present reference outside temperature Tmp equals the low-side temperature T_L, the overcurrent condition is satisfied at a time point when a sum of the time Δt1 and the time Δt2 has reached a time tp3 (where “Δt1<tp3” is assumed). Given that the present reference outside temperature Tmp equals the high-side temperature T_H, the overcurrent condition is satisfied at a time point when a sum of the time Δt1 and the time Δt2 has reached a time tp4 (where “Δt1<tp4” is assumed).

With attention given to the two current values Ip1 and Ip2 for the sake of concretized explanation, there have been described above differences in protection activating time between two cases in which the reference outside temperature Tmp equals the low-side temperature T_L and, in contrast, equals the high-side temperature T_H. However, this is also applicable to other cases in which the protective current value is given by current values other than the current values Ip1 and Ip2.

### Second Practical Example

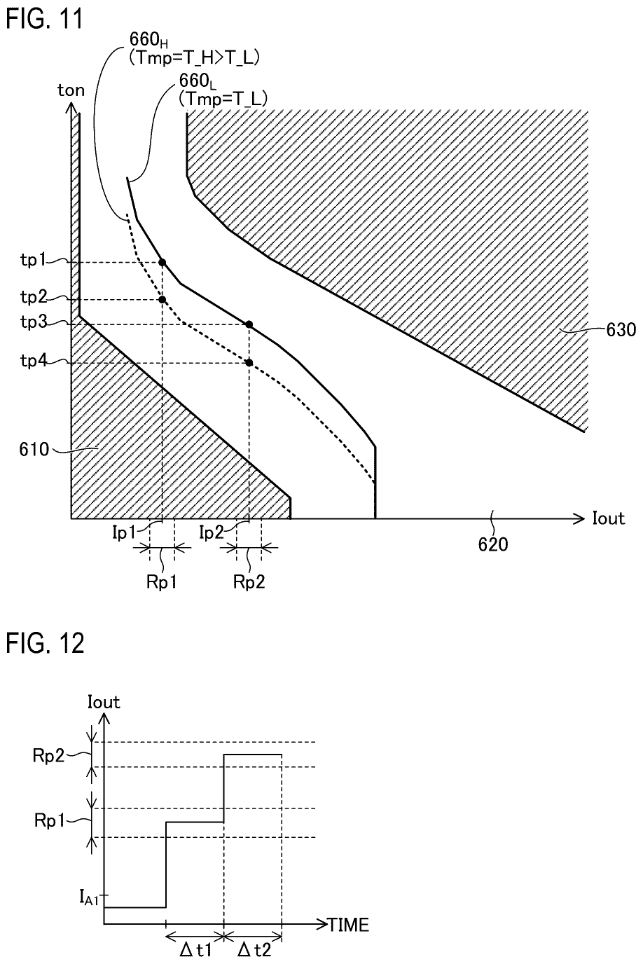

A second practical example will be described. FIG. 11 is referenced. FIG. 11 is a chart in which merely two current ranges Rp1 and Rp2 are added to FIG. 9. Characteristics 660_{L} and 660_{H} shown in FIG. 11 are identical to those shown in the first practical example (FIG. 9). Current values Ip1 and Ip2 as well as times tp1 to tp4 shown in FIG. 11 are identical to those shown in the first practical example (FIG. 9). Therefore, a magnitude relationship of the current values Ip1 and Ip2 as well as a magnitude relationship of the times tp1 to tp4 are also as shown in the first practical example.

The current range Rp1 is a current range having a specified magnitude, and the current value Ip1 is a current value being within the current range Rp1. The current range Rp2 is a current range having a specified magnitude, and the current value Ip2 is a current value being within the current range Rp2. In this case, a lower limit of the current range Rp2 is larger than an upper limit of the current range Rp1. That is, a minimum current value of the current range Rp2 is larger than a maximum current value of the current range Rp1.

The abnormality detection circuit 15 according to the second practical example, with a plurality of individually-different current ranges set therein, decides to which one of the plural current ranges a value of the output current Iout belongs. In a case where the current detection signal Isns is an analog voltage signal having a voltage value proportional to the magnitude of the output current Iout, the abnormality detection circuit 15 is enabled to decide, by using plural comparators, to which one of the plural current ranges a value of the output current Iout belongs. Each comparator may be a window comparator. Two current ranges included in the plural current ranges are the current ranges Rp1 and Rp2. Then, the abnormality detection circuit 15 according to the second practical example sets protection activating times tp individually differently for the plural current ranges and further makes the protection activating times tp for each current range varied in response to the reference outside temperature Tmp.

In more detail, with the reference outside temperature Tmp equal to the low-side temperature T_L, when the output current Iout has continued a state of being within the current range Rp1 for the time tp1, the abnormality detection circuit 15, deciding that the overcurrent condition is satisfied, delivers an overcurrent detection signal Sdet of “1” to the controller 11. With the reference outside temperature Tmp equal to the high-side temperature T_H, when the output current Iout has continued a state of being within the current range Rp1 for the time tp2, the abnormality detection circuit 15, deciding that the overcurrent condition is satisfied, delivers an overcurrent detection signal Sdet of “1” to the controller 11.

With the reference outside temperature Tmp equal to the low-side temperature T_L, when the output current Iout has continued a state of being within the current range Rp2 for the time tp3, the abnormality detection circuit 15, deciding that the overcurrent condition is satisfied, delivers an overcurrent detection signal Sdet of “1” to the controller 11. With the reference outside temperature Tmp equal to the high-side temperature T_H, when the output current Iout has continued a state of being within the current range Rp2 for the time tp4, the abnormality detection circuit 15, deciding that the overcurrent condition is satisfied, delivers an overcurrent detection signal Sdet of “1” to the controller 11.

The controller 11 executes the above-described overcurrent protecting operation a in response to a reception of the overcurrent detection signal Sdet of “1” from the abnormality detection circuit 15.

In comparison between the low-side temperature T_L and the high-side temperature T_H, it holds that “tp1>tp2” and “tp3>tp4”. Also, on the assumption that the reference outside temperature Tmp equals the low-side temperature T_L, since “Ip1<Ip2”, it holds that “tp1>tp3”. On the assumption that the reference outside temperature Tmp equals the high-side temperature T_H, since “Ip1<Ip2”, it holds that “tp2>tp4”.

In addition, in a case where the output current Iout has values varying within a range not less than the foregoing current value I_{A1} (see FIG. 4), after specifically determining a maximum value of the output current Iout during a varying period of the output current Iout, and assuming that the output current Iout continues having the maximum value during the varying period, the abnormality detection circuit 15 may decide whether or not the overcurrent condition is satisfied. As a result of this, safety of the object wiring is ensured. For example, it is assumed, as shown in FIG. 12, that the value of the output current Iout, after abruptly increasing from less than the current value I_{A1} to a current value within the current range Rp1, is held within the current range Rp1 for a time Δt1, thereafter increasing to within the current range Rp2 and being held within the current range Rp2 for a time Δt2. In this case, since the maximum value of the output current Iout during the varying period of the output current Iout is a value within the current range Rp2, the abnormality detection circuit 15 may decide whether or not the overcurrent condition is satisfied, by assuming that the output current Iout continues having the value within the current range Rp2 for the varying period. Then, given that a present reference outside temperature Tmp equals the low-side temperature T_L, the overcurrent condition is satisfied at a time point when a sum of the time Δt1 and the time Δt2 has reached the time tp3 (where “Δt1<tp3” is assumed). Given that the present reference outside temperature Tmp equals the high-side temperature T_H, the overcurrent condition is satisfied at a time point when a sum of the time Δt1 and the time Δt2 has reached the time tp4 (where “Δt1<tp4” is assumed).

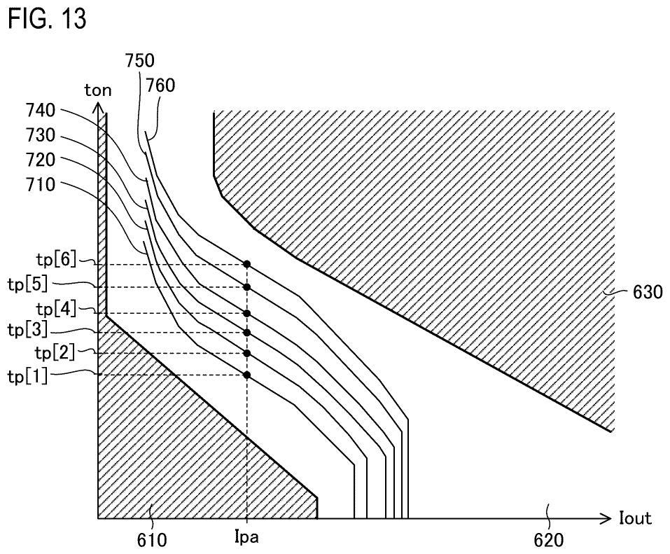

With attention given to the two current ranges Rp1 and Rp2 for the sake of concretized explanation, there have been described above differences in protection activating time between two cases in which the reference outside temperature Tmp equals the low-side temperature T_L and, in contrast, equals the high-side temperature T_H. However, this is also applicable to other current ranges.

<Third practical example A third practical example will be described. FIG. 13 shows characteristics 710 to 760, which are six candidates for the overcurrent protection characteristic. However, those characteristics 710 to 760 are candidates for the overcurrent protection characteristic under a condition that the reference outside temperature Tmp equals a specified standard temperature Tstd. The standard temperature Tstd is arbitrary. The standard temperature Tstd may be set to a standard outside air temperature (e.g., 25° C.) or to a standard temperature of a space where the object wiring is placed (e.g., 50° C.).

The MCU 20 is enabled to transmit to the switch device 10 (controller 11), a characteristic designation command signal for selection and designation of an overcurrent protection characteristic from among the characteristics 710 to 760. The controller 11 stores, in its own memory (not shown), characteristic designation data according to the characteristic designation command signal received from the MCU 20. Then, based on the characteristic designation data, the controller 11 selects and employs any one of the characteristics 710 to 760 as an overcurrent protection characteristic for the standard temperature Tstd.

In this case, it is assumed that when the characteristic designation command signal for selection and designation of the characteristic 710 as an overcurrent protection characteristic is received by the switch device 10, the controller 11 stores characteristic designation data having a value of “1” in the memory. When the characteristic designation data having the value of “1” is stored in the memory, the controller 11 selects and employs the characteristic 710 as an overcurrent protection characteristic for the standard temperature Tstd. Similarly, it is assumed that when a characteristic designation command signal for selection and designation of the characteristic 720 as an overcurrent protection characteristic is received by the switch device 10, the controller 11 stores, in the memory, characteristic designation data having a value of “2”. When the characteristic designation data having the value of “2” is stored in the memory, the controller 11 selects and employs the characteristic 720 as an overcurrent protection characteristic for the standard temperature Tstd. This is applicable also to the characteristics 730 to 760. That is, it is assumed that when the characteristic designation command signal for selection and designation of the characteristic 730, 740, 750 or 760 as an overcurrent protection characteristic is received by the switch device 10, the controller 11 stores, in the memory, characteristic designation data having a value of “3”, “4”, “5” or “6”. When the characteristic designation data having the value of “3”, “4”, “5” or “6” is stored in the memory, the controller 11 selects and employs the characteristic 730, 740, 750 or 760 as an overcurrent protection characteristic for the standard temperature Tstd.

When the characteristic designation data has a value of “1”, the relationship between the protective current value Ip and the protection activating time tp varies in response to the reference outside temperature Tmp with the characteristic 710 referenced. When characteristic designation data has a value of “2”, the relationship between the protective current value Ip and the protection activating time tp varies in response to the reference outside temperature Tmp with the characteristic 720 referenced. This is applicable also when the characteristic designation data has a value of “3”, “4”, “5” or “6”.

The characteristics 710 to 760 differ from one another. FIG. 13 shows a current value Ipa as one example of the protective current value Ip. In a case where the reference outside temperature Tmp equals the standard temperature Tstd and moreover the characteristic designation data has a value of “i”, when the output current Iout has continued a state of having the current value Ipa for a time tp[i], the overcurrent condition is satisfied. The time tp[i] is a protection activating time tp resulting when the current value Ipa is equivalent to the protective current value Ip under a condition that the reference outside temperature Tmp equals the standard temperature Tstd and moreover the characteristic designation data has the value of “i”. The symbol “i” represents a natural number not more than 6. It holds that 0<tp[1]<tp[2]<tp[3]<tp[4]<tp[5]<tp[6].

Under a condition that the reference outside temperature Tmp is higher than the standard temperature Tstd with the characteristic designation data having the value of “i”, when the output current Iout has continued a state of having a current value (Ipa−ΔI) for the time tp[i], the overcurrent condition is satisfied. The current value (Ipa−ΔI) is smaller than the current value Ipa by a current value ΔI. The current value ΔI is variable in response to a difference between the reference outside temperature Tmp and the standard temperature Tstd (the controller 11 or the abnormality detection circuit 15 determines the current value ΔI in response to the difference between the reference outside temperature Tmp and the standard temperature Tstd).

Thus, based on the characteristic designation data according to the characteristic designation command signal derived from the MCU 20, the controller 11 changes over, in plural steps, the overcurrent protection characteristic (i.e., relationship between the protective current value Ip and the protection activating time tp) under the condition that the reference outside temperature Tmp equals the standard temperature Tstd. As a consequence, designers and users of the load driving system SYS are allowed to select a proper overcurrent protection characteristic in view of required margins responsive to characteristics of the load LD or the like, making it possible also to minimize the diameter of the object wiring through selection of proper overcurrent protection characteristics. In addition, although the plural steps in the example of FIG. 13 are six steps, yet a total number of the plural steps may be an arbitrary number not less than 2.

### Fourth Practical Example

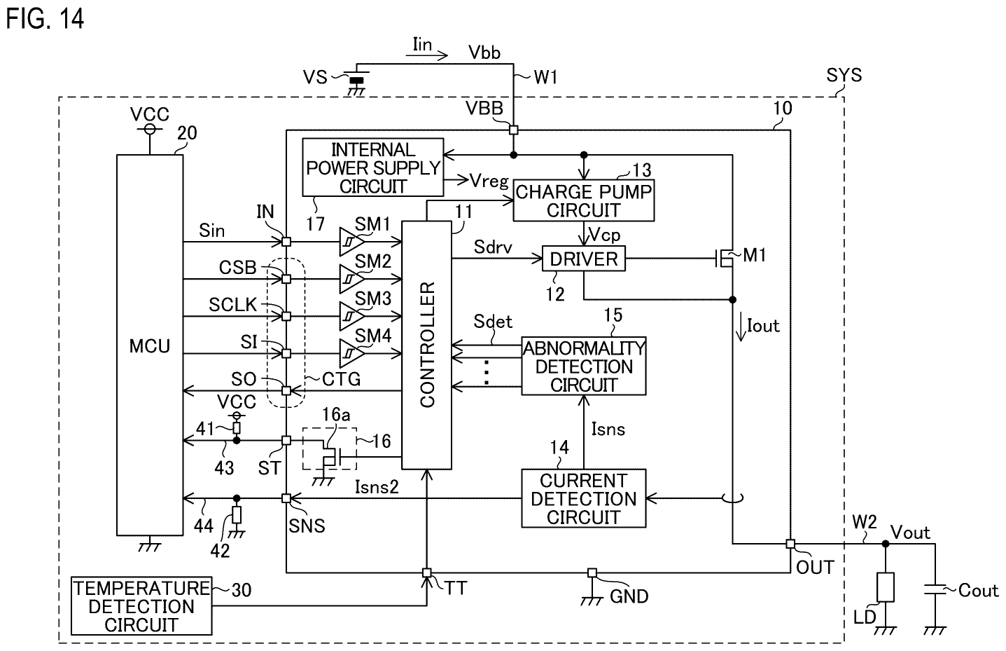

A fourth practical example will be described. As shown in FIG. 14, a temperature detection signal Tsns derived from the temperature detection circuit 30 may be inputted directly to the switch device 10 without being via the MCU 20. In this case, although the temperature detection signal Tsns may be a digital signal, it is assumed here that the temperature detection signal Tsns is an analog voltage signal representing the outside temperature Tmp. Then, the switch device 10 according to the fourth practical example, having a detection signal input terminal TT as one of the external terminals, receives input of a temperature detection signal Tsns by the detection signal input terminal TT.

The temperature detection circuit 30 may execute necessary signal processing (amplification, impedance conversion, etc.) on a signal responsive to the outside temperature Tmp generated inside the temperature detection circuit 30 itself to generate a temperature detection signal Tsns. It may also be construed that a conversion circuit (not shown) operable to execute the signal processing is interposed between the temperature detection circuit 30 and the detection signal input terminal TT.

The temperature detection signal Tsns inputted to the detection signal input terminal TT is inputted to the controller 11 through interconnections within the switch device 10. The controller 11 converts the temperature detection signal Tsns into a digital signal, and specifically determines an outside temperature Tmp on a basis of a resultant digital value of the temperature detection signal Tsns. In the fourth practical example, the outside temperature Tmp specifically determined above is utilized as the reference outside temperature Tmp.

### Fifth Practical Example

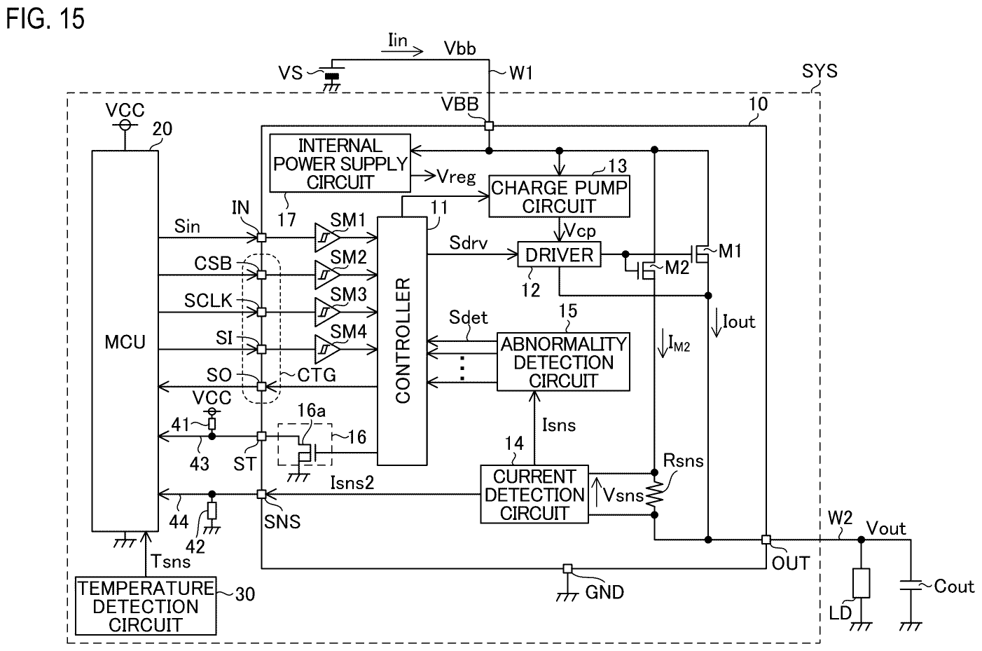

A fifth practical example will be described. A detection method for the output current Iout is described with reference to FIG. 15.

The switch device 10 according to the fifth practical example includes a replica transistor M2 as well as a sense resistor Rsns. The replica transistor M2 is an N-channel MOSFET. A drain of the replica transistor M2 is connected to a drain of the output transistor M1, and a gate of the replica transistor M2 is connected to a gate of the output transistor M1. A source of the replica transistor M2 is connected to a first end of the sense resistor Rsns, and a second end of the sense resistor Rsns is connected to the output terminal OUT (therefore, to a source of the output transistor M1). The replica transistor M2 is equivalent in structure to the output transistor M1, so that a current proportional to the output current Iout flows through the sense resistor Rsns as a drain current I_{M2} of the replica transistor M2. However, the size of the replica transistor M2 is far smaller than the size of the output transistor M1 such that the drain current I_{M2} of the replica transistor M2 is far smaller than the output current Iout.

A sense voltage Vsns is a voltage drop which arises in the sense resistor Rsns. A value of the sense voltage Vsns equals a product of a value of the drain current I_{M2} of the replica transistor M2 multiplied by a value of the sense resistor Rsns. Accordingly, the sense voltage Vsns has a voltage value proportional to the output current Iout. The first end and second end of the sense resistor Rsns are connected to the current detection circuit 14. An input impedance of the current detection circuit 14 as viewed from the sense resistor Rsns is large enough such that a current flowing between the first end and second end of the sense resistor Rsns and the current detection circuit 14 can be regarded as zero. The current detection circuit 14 executes necessary signal processing for the sense voltage Vsns to generate a current detection signal Isns. This signal processing includes, for example, amplification process for amplification of the sense voltage Vsns, and noise reduction process for reduction of noise of the sense voltage Vsns. With the current detection signal Isns being a digital signal, process of digitizing the sense voltage Vsns is included in the foregoing signal processing. Here is assumed, for the sake of concretized explanation, that the current detection signal Isns is an analog voltage signal obtained by amplifying the sense voltage Vsns at a certain amplification factor k_{AMP}. Then, an equation holds that “Isns=I_{M2}×Rsns×k_{AMP}”; given the drain current I_{M2} being k_{A} times the output current Iout, an expression holds that “Isns=Iout×k_{A}×Rsns×k_{AMP}” (where k_{A} is, e.g., within a range of several hundredth to several thousandth). The voltage signal Isns2 delivered to the MCU 20 may also be identical to the current detection signal Isns.

The abnormality detection circuit 15 recognizes a value of the output current Iout on a basis of the current detection signal Isns. For instance, when the current detection signal Isns has a signal value corresponding to the current value Ip1, the abnormality detection circuit 15 decides that the output current Iout has the current value Ip1; when the current detection signal Isns has a signal value corresponding to the current value Ip2, the abnormality detection circuit 15 decides that the output current Iout has the current value Ip2 (see FIG. 9 or FIG. 11). In addition, with the fourth practical example (see FIG. 14) applied to the fifth practical example, the temperature detection signal Tsns derived from the temperature detection circuit 30 may be inputted directly to the switch device 10 without being via the MCU 20 in the configuration of the fifth practical example.

### Sixth Practical Example

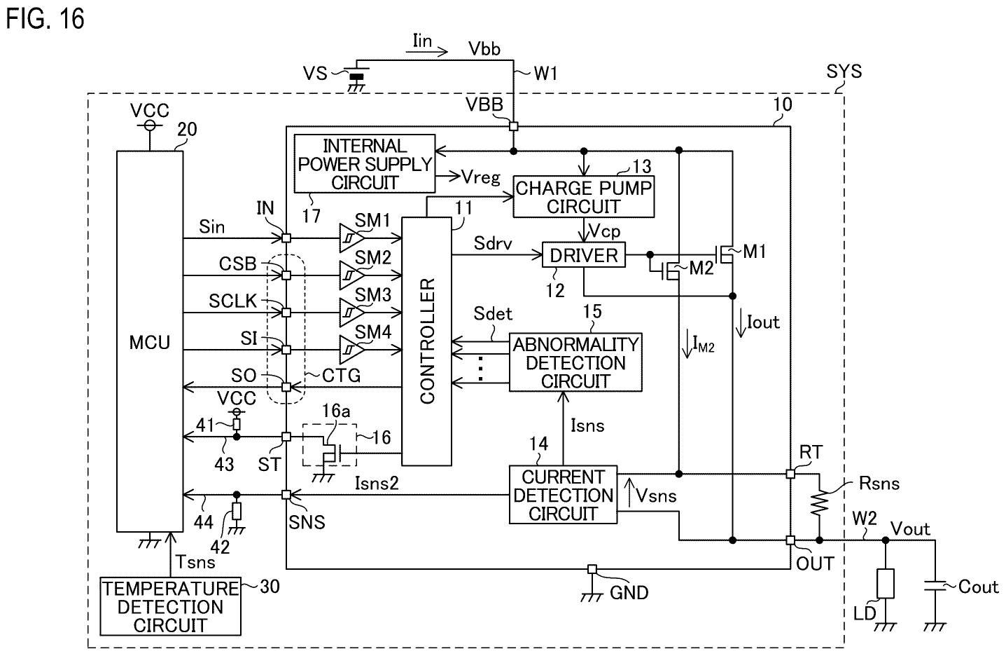

A sixth practical example will be described. Another configuration related to the detection method for the output current Iout is described with reference to FIG. 16. With the configuration according to the fifth practical example referenced as a basis, a sense resistor Rsns is provided outside the switch device 10 in the sixth practical example. Except that the sense resistor Rsns is provided outside the switch device 10, the load driving system SYS according to the sixth practical example is similar in configuration to the load driving system SYS according to the fifth practical example. In addition, with the fourth practical example (see FIG. 14) applied to the sixth practical example, the temperature detection signal Tsns derived from the temperature detection circuit 30 may be inputted directly to the switch device 10 without being via the MCU 20 in the configuration of the sixth practical example.

With an aim of providing the sense resistor Rsns outside the switch device 10, a resistor connecting terminal RT is provided as one of the external terminals in the switch device 10. In the sixth practical example, the first end of the sense resistor Rsns is connected to the resistor connecting terminal RT at a site outside the switch device 10, and the second end of the sense resistor Rsns is connected to the output terminal OUT at a site outside the switch device 10.

The replica transistor M2 according to the sixth practical example includes a drain connected to the drain of the output transistor M1, a gate connected to the gate of the output transistor M1, and a source connected to the resistor connecting terminal RT. Also in the sixth practical example, the drain current I_{M2} of the replica transistor M2 flows to the sense resistor Rsns as a current proportional to the output current Iout, so that a sense voltage Vsns similar to that of the fifth practical example is developed across the sense resistor Rsns.

The first end of the sense resistor Rsns is connected to the current detection circuit 14 via the resistor connecting terminal RT, and the second end of the sense resistor Rsns is connected to the current detection circuit 14 via the output terminal OUT. The input impedance of the current detection circuit 14 as viewed from the sense resistor Rsns is large enough such that a current flowing between the first end and second end of the sense resistor Rsns and the current detection circuit 14 can be regarded as zero. Process of generating the current detection signal Isns from the sense voltage Vsns in the current detection circuit 14 is similar to that of the fifth practical example.

Based on the current detection signal Isns, the abnormality detection circuit 15 recognizes a value of the output current Iout. For instance, given that the current detection signal Isns has a signal value corresponding to the current value Ip1, the abnormality detection circuit 15 decides that the output current Iout has the current value Ip1; given that the current detection signal Isns has a signal value corresponding to the current value Ip2, the abnormality detection circuit 15 decides that the output current Iout has the current value Ip2 (see FIG. 9 or FIG. 11).

Therefore, it becomes practicable to adjust the overcurrent protection characteristic by adjusting the value of the sense resistor Rsns, which is an external resistor for the switch device 10. The result is that the overcurrent protection characteristic is shifted leftward or rightward on the graph of FIG. 6 depending on variations in the value of the sense resistor Rsns.

In addition, also in the fifth practical example, the sense resistor Rsns contained in the switch device 10 may be so configured that its value can be changed over in plural steps, allowing the controller 11 to adjust and change the value of the sense resistor Rsns in response to a command signal derived from the MCU 20. However, as in the sixth practical example, the configuration in which the sense resistor Rsns is provided outside the switch device 10 yields higher-precision adjustability for the value of the sense resistor Rsns.

### Seventh Practical Example

A seventh practical example will be described.

The switch device 10 contains a control circuit that executes the above-described overcurrent protecting operation a on a basis of the outside temperature Tmp and the output current Iout flowing through the output transistor M1. The control circuit is configured by including at least the controller 11. It may be construed that the controller 11 itself is equivalent to the control circuit, or that the driver 12, the current detection circuit 14 and the abnormality detection circuit 15 are entirely or partly included, in addition to the controller 11, in component elements of the control circuit.

Whereas the switch device 10 is employed as a so-called high-side switch in the configuration exemplified in FIG. 1 and others, the switch device 10 may also be employed as a so-called low-side switch. That is, the load LD may be inserted in series to the input wiring W1. In this case, the terminal VBB functions as a load connecting terminal, and the output terminal OUT is connected directly to the ground through the output wiring W2 (or the ground terminal GND is employed as the output terminal OUT). Besides, the power supply voltage VCC may separately be supplied to the switch device 10 as a power supply voltage dedicated to drive of the switch device 10 (an external terminal for reception of the power supply voltage VCC may appropriately be added to the switch device 10). In a case where the switch device 10 is employed as the so-called low-side switch, the charge pump circuit 13 is unnecessary, and the internal power supply circuit 17 is required only to generate the internal power supply voltage Vreg from the power supply voltage VCC.

The present embodiment has been described above as an example in which the switch device 10 is applied to a vehicle VHCL. However, the switch device 10 may be applied to arbitrary destinations without being limited to the vehicle VHCL. For instance, the switch device 10 may be mounted on arbitrary industrial machines or arbitrary household electrical appliances.

With regard to any arbitrary signal or voltage, the relationship between high level and low level of the signal or voltage may be reversed relative to the above-described one without impairing the above-described gist.

Channel type of FETs (Field Effect Transistors) described in the foregoing embodiment is only exemplary. The channel type of any arbitrary FET may be changed over between P-channel and N-channel without impairing the above-described gist.

Unless any disadvantages arise, the above-described arbitrary transistor may be a transistor of any arbitrary type. For example, unless any disadvantages arise, any arbitrary transistor described as a MOSFET hereinabove may be replaced with a junction FET, an IGBT (Insulated Gate Bipolar Transistor), or a bipolar transistor. An arbitrary transistor has a first electrode, a second electrode and a control electrode. In a FET, one of the first electrode and the second electrode is drain and the other is source, the control electrode being gate. In an IGBT, one of the first electrode and the second electrode is collector and the other is emitter, the control electrode being gate. In a bipolar transistor not belonging to IGBTs, one of the first electrode and the second electrode is collector and the other is emitter, the control electrode being base.

The embodiment of the disclosure may be changed or modified in various ways, as appropriately, within the scope of the technical ingenuity exhibited in the appended claims. The embodiment described hereinabove should be understood to be an example of the disclosure, and senses of terms of the disclosure or its component elements are not limited to those described in the embodiment. Concrete numerical values included in the above description are illustrative only, and of course may be changed to various numerical values.

### APPENDICES

Below provided are appendices relevant to the present disclosure described with specific configuration examples in the foregoing embodiment.

A switch device (10) according to one aspect of the present disclosure includes an input terminal (VBB), an output terminal (OUT), an output transistor (M1) provided between the input terminal and the output terminal, and a control circuit (including at least a controller 11) configured to, under its control, turn on or off the output transistor in response to a control signal (Sin) supplied to the switch device, wherein the control circuit is enabled to execute a protective operation by which the output transistor is switched over from on to off independent of the control signal on a basis of an outside temperature (Tmp) of the switch device and an output current (Iout) flowing through the output transistor (first configuration).

With this configuration, it becomes practicable to properly ensure safety of components (wirings etc.) which are connected to the input terminal or the output terminal and affected by the outside temperature.

In the switch device according to the first configuration, as an allowable modification, when the output current has continued a state of having a protective current value (Ip) for a protection activating time (tp), the control circuit executes the protective operation, and moreover the control circuit makes the protection activating time decreased with increasing outside temperature (second configuration).

Making the protection activating time decreased with increasing outside temperature makes it possible to properly ensure safety of components (wirings etc.) which are connected to the input terminal or the output terminal and affected by the outside temperature.

In the switch device according to the second configuration (see FIG. 9), as an allowable modification, with the outside temperature equal to a first temperature (T_L), when the output current has continued the state of having the protective current value (Ip1) for a first protection activating time (tp1), the control circuit executes the protective operation, and with the outside temperature equal to a second temperature (T_H) higher than the first temperature, when the output current has continued the state of having the protective current value (Ip1) for a second protection activating time (tp2) shorter than the first protection activating time, the control circuit executes the protective operation (third configuration).

In the switch device according to the second configuration (see FIG. 9), as an allowable modification, with the outside temperature equal to a first temperature (T_L), when the output current has continued a state of having a first protective current value (Ip1) for a first protection activating time (tp1), the control circuit executes the protective operation; with the outside temperature equal to a second temperature (T_H) higher than the first temperature, when the output current has continued the state of having the first protective current value (Ip1) for a second protection activating time (tp2) shorter than the first protection activating time, the control circuit executes the protective operation; with the outside temperature equal to the first temperature (T_L), when the output current has continued a state of having a second protective current value (Ip2) for a third protection activating time (tp3), the control circuit executes the protective operation; with the outside temperature equal to the second temperature (T_H), when the output current has continued the state of having the second protective current value (Ip2) for a fourth protection activating time (tp4) shorter than the third protection activating time, the control circuit executes the protective operation; and the second protective current value is larger than the first protective current value, the third protection activating time is shorter than the first protection activating time, and the fourth protection activating time is shorter than the second protection activating time (fourth configuration).

In the switch device according to the second configuration (see FIG. 11), as an allowable modification, with the outside temperature equal to a first temperature (T_L), when the output current has continued a state of being within a specific current range (Rp1) containing the protective current value (Ip1) for a first protection activating time (tp1), the control circuit executes the protective operation, and with the outside temperature equal to a second temperature (T_H) higher than the first temperature, when the output current has continued the state of being within the specific current range (Rp1) for a second protection activating time (tp2) shorter than the first protection activating time, the control circuit executes the protective operation (fifth configuration).

In the switch device according to the second configuration, as an allowable modification, with the outside temperature equal to a first temperature (T_L), when the output current has continued a state of being within a first specific current range (Rp1) containing a first protective current value (Ip1) for a first protection activating time (tp1), the control circuit executes the protective operation; with the outside temperature equal to a second temperature (T_H) higher than the first temperature, when the output current has continued the state of being within the first specific current range for a second protection activating time (tp2) shorter than the first protection activating time, the control circuit executes the protective operation; with the outside temperature equal to the first temperature, when the output current has continued a state of being within a second specific current range (Rp2) containing a second protective current value (Ip2) for a third protection activating time (tp3), the control circuit executes the protective operation; with the outside temperature equal to the second temperature, when the output current has continued the state of being within the second specific current range (Rp2) for a fourth protection activating time (tp4) shorter than the third protection activating time, the control circuit executes the protective operation; and a lower limit of the second specific current range is larger than an upper limit of the first specific current range, the third protection activating time is shorter than the first protection activating time, and the fourth protection activating time is shorter than the second protection activating time (sixth configuration).

In the switch device according to any one of the first to sixth configurations, as an allowable modification, the outside temperature is a temperature of a space where an input wiring (W1) connected to the input terminal and provided outside the switch device, or an output wiring connected to the output terminal and provided outside the switch device, is placed (seventh configuration).

With this configuration, safety of the input wiring or the output wiring, whichever is affected by the outside temperature, can be ensured properly.

In the switch device according to any one of the first to seventh configurations, as an allowable modification, the control circuit changes over, in plural steps, a relationship between the protective current value and the protection activating time under a condition that the outside temperature equals a specified temperature (Tstd) (eighth configuration).

In the switch device according to any one of the first to eighth configurations, as an allowable modification, the control circuit is supplied with a signal indicative of the outside temperature from an external control unit (20) that supplies the switch device with the control signal (ninth configuration).

In the switch device according to any one of the first to eighth configurations, as an allowable modification, the control circuit is supplied with a signal indicative of the outside temperature, without being via an external control unit (20), from an external circuit (30) other than the external control unit that supplies the switch device with the control signal (tenth configuration).

A load driving system (SYS) according to one aspect of the disclosure includes: the the switch device according to any one of the first to eighth configurations; an external control unit (20) configured to supply the switch device with the control signal; and a temperature detection circuit (30) configured to detect the outside temperature, allowing the load driving system to supply a load (LD) with the output current, wherein a detection result of the outside temperature by the temperature detection circuit is transmitted to the switch device via the external control unit or without being via the external control unit (eleventh configuration).

What is claimed is:

1. A switch device comprising: an input terminal, an output terminal, an output transistor provided between the input terminal and the output terminal, and a control circuit configured to, under its control, turn on or off the output transistor in response to a control signal supplied to the switch device, wherein
the control circuit is enabled to execute a protective operation by which the output transistor is switched over from on to off independent of the control signal on a basis of an outside temperature of the switch device and an output current flowing through the output transistor.

2. The switch device according to claim 1, wherein
when the output current has continued a state of having a protective current value for a protection activating time, the control circuit executes the protective operation, and
the control circuit makes the protection activating time decreased with increasing outside temperature.

3. The switch device according to claim 2, wherein
with the outside temperature equal to a first temperature, when the output current has continued the state of having the protective current value for a first protection activating time, the control circuit executes the protective operation, and
with the outside temperature equal to a second temperature higher than the first temperature, when the output current has continued the state of having the protective current value for a second protection activating time shorter than the first protection activating time, the control circuit executes the protective operation.

4. The switch device according to claim 2, wherein
with the outside temperature equal to a first temperature, when the output current has continued a state of having a first protective current value for a first protection activating time, the control circuit executes the protective operation,
with the outside temperature equal to a second temperature higher than the first temperature, when the output current has continued the state of having the first protective current value for a second protection activating time shorter than the first protection activating time, the control circuit executes the protective operation,
with the outside temperature equal to the first temperature, when the output current has continued a state of having a second protective current value for a third protection activating time, the control circuit executes the protective operation,
with the outside temperature equal to the second temperature, when the output current has continued the state of having the second protective current value for a fourth protection activating time shorter than the third protection activating time, the control circuit executes the protective operation, and
the second protective current value is larger than the first protective current value, the third protection activating time is shorter than the first protection activating time, and the fourth protection activating time is shorter than the second protection activating time.

5. The switch device according to claim 2, wherein
with the outside temperature equal to a first temperature, when the output current has continued a state of being within a specific current range containing the protective current value for a first protection activating time, the control circuit executes the protective operation, and
with the outside temperature equal to a second temperature higher than the first temperature, when the output current has continued the state of being within the specific current range for a second protection activating time shorter than the first protection activating time, the control circuit executes the protective operation.

6. The switch device according to claim 2, wherein
with the outside temperature equal to a first temperature, when the output current has continued a state of being within a first specific current range containing a first protective current value for a first protection activating time, the control circuit executes the protective operation,
with the outside temperature equal to a second temperature higher than the first temperature, when the output current has continued the state of being within the first specific current range for a second protection activating time shorter than the first protection activating time, the control circuit executes the protective operation,
with the outside temperature equal to the first temperature, when the output current has continued a state of being within a second specific current range containing a second protective current value for a third protection activating time, the control circuit executes the protective operation,
with the outside temperature equal to the second temperature, when the output current has continued the state of being within the second specific current range for a fourth protection activating time shorter than the third protection activating time, the control circuit executes the protective operation, and
a lower limit of the second specific current range is larger than an upper limit of the first specific current range, the third protection activating time is shorter than the first protection activating time, and the fourth protection activating time is shorter than the second protection activating time.

7. The switch device according to claim 1, wherein
the outside temperature is a temperature of a space where an input wiring connected to the input terminal and provided outside the switch device, or an output wiring connected to the output terminal and provided outside the switch device, is placed.

8. The switch device according to claim 1, wherein
the control circuit changes over, in plural steps, a relationship between the protective current value and the protection activating time under a condition that the outside temperature equals a specified temperature.

9. The switch device according to claim 1, wherein
the control circuit is supplied with a signal indicative of the outside temperature from an external control unit that supplies the switch device with the control signal.

10. The switch device according to claim 1, wherein
the control circuit is supplied with a signal indicative of the outside temperature, without being via an external control unit, from an external circuit other than the external control unit that supplies the switch device with the control signal.

11. A load driving system comprising:
the switch device according to claim 1;
an external control unit configured to supply the switch device with the control signal; and
a temperature detection circuit configured to detect the outside temperature, allowing the load driving system to supply a load with the output current, wherein
a detection result of the outside temperature by the temperature detection circuit is transmitted to the switch device via the external control unit or without being via the external control unit.
